(19) United States
(12) Patent Application Publication
(10) Pub. No.: US 2009/0121219 A1
(43) Pub. Date: May 14, 2009

(54) Carbon nanotubes, method of growing the same, hybrid structure and method of growing the hybrid structure, and light emitting device

(76) Inventors: Byong-gwon Song, Yongin-si (KR); Jin-pyo Hong, Seoul (KR); Yong-wan Jin, Yongin-si (KR); Seung-nam Cha, Yongin-si (KR); Jong-hyun Lee, Seoul (KR); Jae-hwan Ha, Seoul (KR)

Correspondence Address: ROBERT E. BUSHNELL & LAW FIRM, 2029 K STREET NW, SUITE 600, WASHINGTON, DC, 20006-1004, US

(21) Appl. No.: 12/232,246

(22) Filed: Sep. 12, 2008

(30) Foreign Application Priority Data
Oct. 24, 2007 (KR) 10-2007-0107432

(51) Int. Cl. H01L 33/00; B05D 5/12; B05D 3/06

(52) U.S. Cl. 257/43; 438/104; 427/70; 427/540; 427/554; 977/742; 257/E33.019

(57) ABSTRACT

Provided is a method of growing carbon nanotubes (CNTs) by forming a catalyst layer that is used to facilitate growth of CNTs to have a multi-layer structure; and injecting a carbon-containing gas to the catalyst layer to grow CNTs, and light emitting devices fabricated by incorporating the CNTs grown.

### CLAIM OF PRIORITY

This application makes reference to, incorporates the same herein, and claims all benefits accruing under 35 U.S.C. §119 from an application for Carbon Nanotubes, Method of Growing the Same, Hybrid Structure and Method of Growing the Hybrid Structure, and Light Emitting Device earlier filed in the Korean Intellectual Property Office on the 24 of Oct. 2007 and there duly assigned Serial No. 2007-0107432.

### BACKGROUND OF THE INVENTION

1. Field of the Invention

The present invention relates to carbon nanotubes (CNTs), a method of growing the same, a hybrid structure including the CNTs, a method of growing the hybrid structure, and a light emitting device including the hybrid structure.

2. Description of the Related Art

Carbon nanotubes (CNT) have very small diameters and very high aspect ratios. CNTs are structured such that a sheet consisting of carbon atoms which have a graphite structure and are arranged in a hexagonal structure is rolled into a cylinder. According to the structure of CNTs, CNTs have conductive properties or semi-conductive properties.

Also, CNTs have a very strong mechanical strength and high thermal conductivity. Therefore, CNTs are used in a wide range of applications, such as field emission displays (FED), back light devices (BLU) for liquid crystal display (LCD), or nanoelectronic devices.

Cold cathode fluorescent lamp (CCFL) BLUs which are necessarily used in LCD device include mercury (Hg) and thus, their manufacturing process is complex and causes environmental problems. Therefore, a BLU using a light emitting diode (LED) and a flat fluorescent BLU have been developed to replace CCFL BLUs. Specifically, a BLU using CNTs have been developed.

CNT BLUs that operated on the basis of a field emission principle of CNTs, do not use Hg. So, CNT BLUs are environmentally friendly, have a simple structure, and can be manufactured even thinner.

Conventional CNT BLUs however require, in addition to CNTs, low voltage fluorescent materials.

### SUMMARY OF THE INVENTION

The present invention provides carbon nanotubes (CNTs) using a catalyst layer having a multi-layer structure, a method of growing the CNTs, a hybrid structure including the CNTs, a method of growing the hybrid structure, and a light emitting device including the hybrid structure.

According to an aspect of the present invention, there is provided a method for growing carbon nanotubes (CNTs); the method includes the formation of a catalyst layer that is used to facilitate growth of CNTs to have a multi-layer structure; and the injection of a carbon-containing gas to the catalyst layer to grow CNTs.

The catalyst layer may include at least one first layer which includes Zn; and at least one second layer which does not include Zn, in which the first layer and the second layer are alternatively stacked.

The second layer may include Ni.

The catalyst layer may be surface-treated to form catalytic grains therein.

The catalytic grains may be formed by a plasma treatment, a laser treatment, or a heat treatment.

The carbon-containing gas may include at least one gas selected from the group consisting of CH₄, C₂H₂, C₂H₄, C₂H₆, CO, and CO₂ and is injected together with at least one gas selected from the group consisting of H₂, N₂, O₂, H₂O, and Ar.

A buffer layer may be further formed between the substrate and the catalyst layer.

The catalyst layer may include at least one first layer including Zn and at least one second layer including Ni, wherein the first and second layers are alternatively stacked, the catalyst layer is surface-treated to form catalytic grains therein, and a buffer layer is formed between the substrate and the catalyst layer.

The catalyst layer may include Zn, and the method may further include selectively removing a material of the catalyst layer such that Zn is remained in an end portion of the grown CNTs.

According to another aspect of the present invention, there is provided a method of forming a hybrid structure, the method including the formation of CNTs using the method; and the growth of a nano structure on the CNTs to form a hybrid structure.

The catalyst layer remaining in an end portion of the CNTs grown may include Zn, and the nano structure may include ZnO.

The nano structure may be grown by using the Zn remaining in an end portion of the grown CNTs as a seed.

A p-n junction may be formed between the CNTs and the nano structure.

The catalyst layer comprises Zn, and before growing the nano structure, the method further includes selectively removing a material of the catalyst layer so that Zn remains in an end portion of the CNTs grown.

According to another aspect of the present invention, there is provided a CNT having a multilayer that is used as a catalyst in an apical end, and being formed on a substrate.

According to another aspect of the present invention, there is provided a hybrid structure including a CNT on a substrate using a catalyst having a multi-layer structure; and a nano structure grown on the CNT.

According to another aspect of the present invention, there is provided a light emitting device including a substrate; the hybrid structure on the substrate; and an electrode electrically connected to the hybrid structure.

The light emitting device may be used as a back light for liquid crystal display.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIGS. 1-3 are sectional views illustrating a method of growing CNTs according to the steps of an embodiment of the present invention;

FIG. 4A illustrates a stacked structure of a glass substrate, a Cr buffer layer having a thickness of 200 nm, and a catalyst layer having a multi-layer structure, which is used to form CNTs according to an embodiment of the present invention, in which the catalyst layer includes a 3 nm-thick Zn layer, a 3 nm-thick Ni layer, a 3 nm-thick Zn layer, and a 3 nm-thick Ni layer and has the entire thickness of 12 nm, in which the Zn layer and the Ni layer are alternatively stacked;

FIG. 4B is an atomic force microscopic (AFM) image of the surface of the stack structure of FIG. 4A after the surface is plasma-treated with an ammonia gas at 50 W treatment power;

FIG. 4C is a scanning electron microscopic (SEM) image of CNTs which are grown after catalytic grains are formed by the surface treatment as illustrated in FIG. 4B;

FIG. 5A illustrates a stacked structure of a glass substrate, a 200 nm-thick Cr buffer layer, and a 15 nm-thick Ni catalyst layer, which is used as a comparative example;

FIG. 5B is an AFM image of the surface of the stacked structure of FIG. 5A after the surface is plasma-treated with an ammonia gas at 50 W treatment power;

FIG. 5C is a SEM image of CNTs which are grown after catalytic grains are formed by the surface treatment as illustrated in FIG. 5B;

FIG. 6 is a Cartesian coordinate graph showing results of a Raman spectra measurement of CNTs synthesized using a catalyst layer having a multi-layer structure and a G/D ratio;

FIG. 7 is a transmission electron microscopic (TEM) image of an apical end of a CNT synthesized using the catalyst layer having a multi-layer structure as illustrated in FIG. 4A;

FIGS. 8 and 9 illustrate a method of growing a nano structure on CNTs grown using a method of growing CNTs according to an embodiment of the present invention so as to form a hybrid structure; and

FIG. 10 is a schematic view of a light emitting device including the hybrid structure of FIG. 9, according to an embodiment of the present invention.

### DETAILED DESCRIPTION OF THE INVENTION

Carbon nanotubes (CNTs) are structured such that a sheet consisting of carbon atoms which have a graphite structure are arranged in a hexagonal structure that is rolled into a cylinder. When a CNT consists of one sheet, such CNT is called as a single-wall carbon nanotube (SWNT). When a CNT consists of about 2-5 sheets, such CNT is called as a thin multi-wall carbon nanotube (t-MWNT). When a CNT consists of many sheets, for example, more than five (5) sheets, such CNT is called as a multi-wall carbon nanotube (MWNT).

In general, a catalyst layer that is used to form CNTs is a single layer, and can be formed of Ni, Invar, or Fe.

Such single-layer catalyst layer is used to form a MWNT by plasma enhanced chemical vapor deposition (PECVD) at low temperature. In this regard, however, there is a limitation on reducing a diameter of CNTs or the number of walls of a MWNT.

On the other hand, according to the present invention, a catalyst layer has a multi-layer structure. Such a catalyst layer having a multi-layer structure may be useful to synthesize a MWNT in small diameters by PECVD at low temperature.

Hereinafter, with reference to the accompanying drawings, CNTs, a method of growing CNTs, a hybrid structure, a method of growing the hybrid structure, and a light emitting device will now be described in detail. In the drawings, the thicknesses of layers, the size of catalytic grains, and CNTs are exaggerated for the sake of clarity.

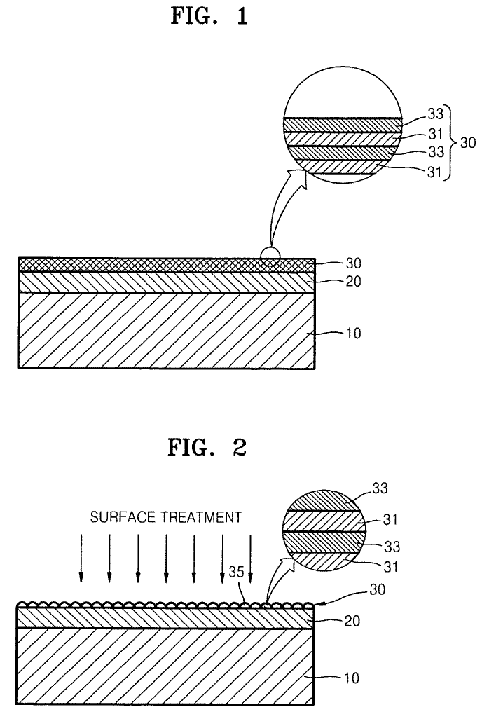

FIGS. 1-3 are cross sectional views illustrating a method of growing CNTs according to the steps of an embodiment of the present invention.

Referring to FIG. 1, a catalyst layer 30 having a multi-layer structure is formed on a substrate 10 to facilitate growth of CNTs. A buffer layer 20 may be further formed between the substrate 10 and the catalyst layer 30 having a multi-layer structure.

The substrate 10 may be an optically transparent substrate. For example, the substrate 10 may be a glass substrate or a transparent plastic substrate. The substrate 10 can also be a substrate made of a semiconducting material.

The buffer layer 20 may include a metallic material, for example, Cr. The buffer layer 20 can also include other kinds of metal, such as Al.

The catalyst layer 30 includes at least one first layer 31 which includes Zn; and at least one second layer 33 which does not include Zn, in which the first layer 31 and the second layer 33 may be alternatively stacked. The second layer 33 may include, for example, Ni or an alloy including Ni. The second layer 33 can also include any catalytic metal that is conventionally used to form CNTs. Such material may be Fe, Invar, Co, or an alloy thereof. Referring to FIG. 1, the catalyst layer 30 may alternatively have a four-layer structure including a first layer 31, a second layer 33, a first layer 31, and a second layer 33.

The catalyst layer 30 having a multi-layer structure may be formed by, for example, electron-beam evaporation, chemical vapor deposition, or sputtering.

After a catalyst layer 30 having a multi-layer structure is formed as described above, the catalyst layer 30 is surface-treated as illustrated in FIG. 2 to form catalytic grains 35.

The catalytic grains 35 may be formed by a post-treatment process, such as a plasma treatment, a laser treatment, or a rapid thermal annealing (RTA.) For example, the plasma treatment may use, for instance, Ar gas or NH₃ gas. The laser treatment may immediately raise a peak power. For example, the laser treatment may be performed by irradiating catalyst layer 30 with a pulsed laser beam to form catalytic grains 35. The RTA may use, for example, an infra red (IR) source.

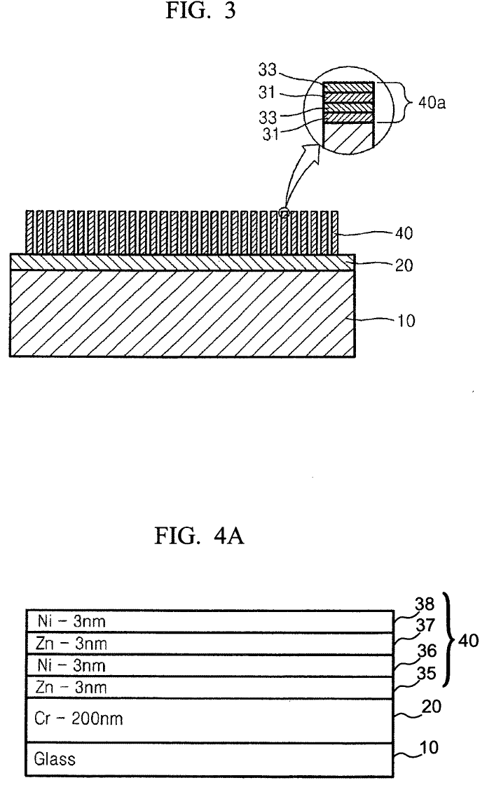

After catalyst layer 30 having a multi-layer structure is surface-treated to form catalytic grains 35 as described above, a carbon-containing gas is injected to the catalyst layer 30 having the catalytic grains 35. As a result, CNTs 40 may be grow as illustrated in FIG. 3. The CNTs 40 may grow by, for example, PECVD at low temperature.

The carbon-containing gas may include, for example, at least one gas selected from the group consisting of CH₄, C₂H₂, C₂H₄, C₂H₆, CO, and CO₂. The carbon-containing gas may be injected together with, for example, at least one gas selected from the group consisting of H₂, N₂, O₂, H₂O, and Ar gas.

Such grown CNTs 40 having a multi-layer structure which have been grown using the catalyst layer 30, may have an apical end 40a including a multi-layer catalyst as illustrated in an enlarged view of FIG. 3. The multi-layer catalyst in the apical end 40a may be identified by the TEM image of FIG. 7.

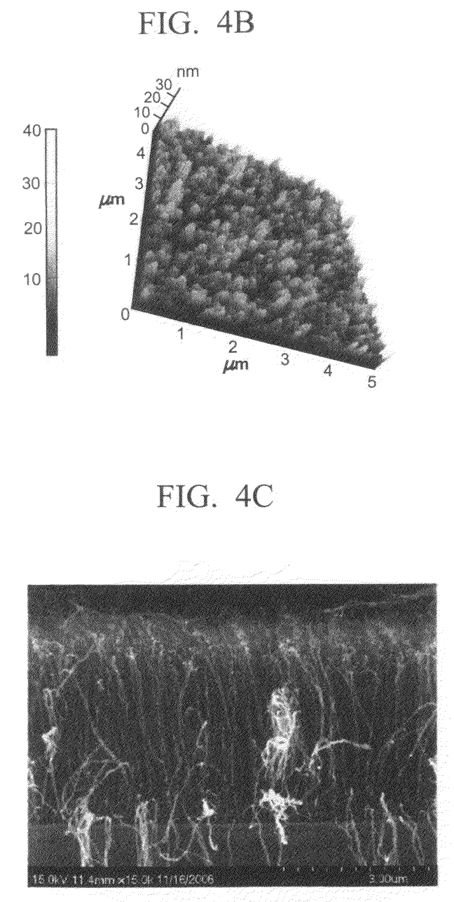

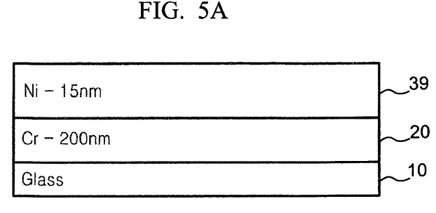

FIG. 4A illustrates the stack structure of a glass substrate 10, a Cr buffer layer 20 having a thickness of 200 nm, and a catalyst layer having a multi-layer structure, which is used to form CNTs 40 according to an embodiment of the present invention, in which the catalyst layer includes a 3 nm-thick Zn layer 35, a 3 nm-thick Ni layer 36, a 3 nm-thick Zn layer 37, and a 3 nm-thick Ni layer 38, and has the entire thickness of 12 nm. FIG. 4B is an atomic force microscopic (AFM) image of the surface of the stack structure of FIG. 4A after the surface is plasma-treated with an ammonia gas of 50 W treatment power. FIG. 4C is a scanning electron microscopic (SEM) image of CNTs which are grown after catalytic grains are formed by the surface treatment as illustrated in FIG. 4B.

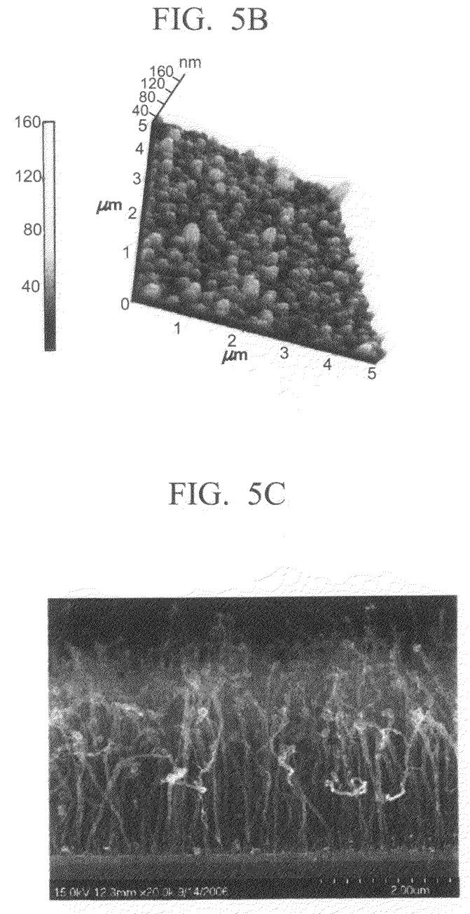

As a comparative example using a single-layer catalyst layer, FIG. 5A illustrates the stack structure of a glass substrate 10, a 200 nm-thick Cr buffer layer 20, and a 15 nm-thick Ni catalyst layer 39. FIG. 5B is an AFM image of the surface of the stack structure of FIG. 5A after the surface is plasma-treated with an ammonia gas at 50 W treatment power. FIG. 5C is a SEM image of CNTs which are grown after catalytic grains are formed by the surface treatment as illustrated in FIG. 5B.

Referring to FIGS. 4C and 5C, CNTs are grown using C₂H₂ gas together with H₂ gas and a substrate 10 at 400° C. while RF power of 20 W is applied thereto.

Comparing the atomic force microscopic images of the surfaces of the stack structures illustrated by FIG. 4B with FIG. 5B, it may be seen that when a catalyst layer has a multi-layer structure, catalytic grains are formed in smaller thicknesses and in more uniform sizes than when a catalyst layer has a single-layer structure. Such results can be identified by comparison of the scanning electron microscopic images of the CNTs illustrated by FIGS. 4C and 5C.

As a catalystic grain is smaller, grown CNTs have narrower diameters. This is made apparent by comparing the size of the catalystic grains with reference to FIGS. 4B and 5B. That is, when a catalyst layer has a multi-layer structure, grown CNTs have narrower diameters than when a catalyst layer has a single layer. This is also apparent with reference to FIGS. 4C and 5C.

Comparing FIG. 4C and FIG. 5C, when a catalyst layer has a multi-layer structure, the CNTs grown are longer and thinner than when a catalyst layer has a single-layer structure. When CNTs are grown using a catalyst layer having a multi-layer structure, the CNTs grown may have a diameter of, for example, about 20 nm. On the other hand, when CNTs are grown using a catalyst layer having a single-layer structure, the CNTs grown may have a diameter of, for example, about 40 nm.

When such long and thin CNTs are used in, for example, a field emission display (i.e., a “FED”), excellent properties can be obtained. That is, thin CNTs means that CNTs are SWNTs or t-MWNTs. FEDs using SWNTs or t-MWNTs may be operated at a relatively low voltage.

As described above, the CNTs 40 according to the present invention can be synthesized to be SWNTs, or t-MWNTs having excellent electrical properties of SWNT and structural advantages of MWNT, by using a catalyst layer having a multi-layer structure.

Also, for example, when a Zn/Ni catalyst layer having a multi-layer structure is used, MWNT can be synthesized in small diameters on substrate 10 even when plasma enhanced chemical vapor deposition (PECVD) is applied thereto at low temperature.

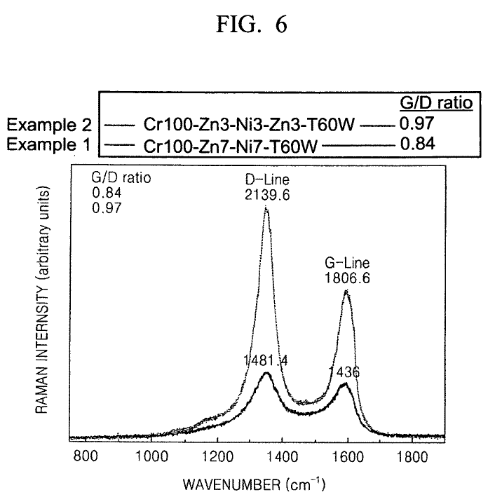

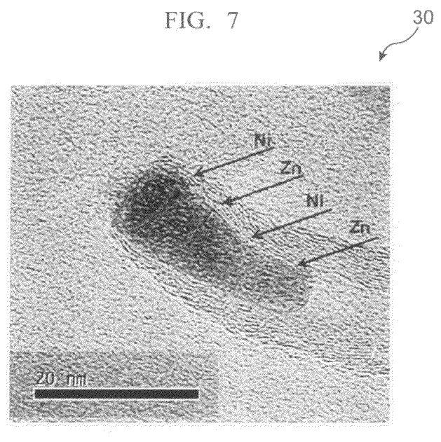

FIG. 6 is a Cartesian coordinate graph showing results of a Raman spectra measurement of CNTs synthesized using the catalyst layer 30 having a multi-layer structure and a G/D ratio. The quality of the CNTs 40 may be identified by a ratio of G (graphite peak) to D (disorder-peak), that is, by a G/D ratio.

Referring to FIG. 6, when the catalyst layer 30 includes a double-layer structure including a 7 nm-thick Zn layer and a 7 nm-thick Ni layer and has the entire thickness of 14 nm in Example 1, the G/D ratio is 0.84; and when the catalyst layer 30 has a four-layer structure of a 3 nm-thick Zn layer, a 3 nm-thick Ni layer, a 3 nm-thick Zn layer, and a 3 nm-thick Ni layer, in which the Zn layer and Ni layer are alternatively stacked, and has the entire thickness of 12 nm in Example 2, the G/D ratio is 0.97. That is, when the catalyst layer 30 has a four-layer structure, the G/D ratio is greater than when the catalyst layer 30 has a double-layer structure.

FIG. 7 is a transmission electron microscopic (TEM) image of an apical end of a CNT synthesized from catalyst layer 30 fabricated with a multi-layer structure such as that illustrated in FIG. 4A. Referring to FIG. 7, the apical ends of the CNTs have the multi-layer structure of the catalyst layer. That is, when a catalyst layer has a sequential stack structure fabricated with a Zn layer, a Ni layer, a Zn layer, and a Ni layer, such stack structure of the catalyst layer remains in an apical end of CNTs.

Therefore, a mixture structure with a wide-band gap material, such as a Zn oxide nano rod, can be formed through a selective process of removing the catalytic metal remaining in the apical ends 40a of the CNTs 40.

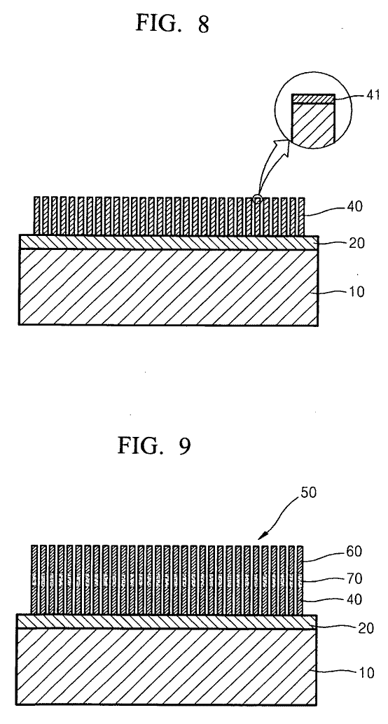

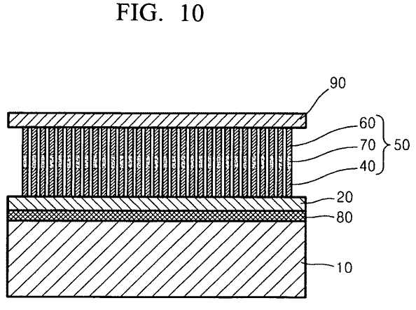

FIGS. 8 and 9 illustrate a method of growing a nano structure 60 on CNTs 40 grown using the method that may be practiced as an embodiment of the present invention to obtain a hybrid structure 50.

First, the CNTs 40 are grown on one major surface of buffer layer 20 on a substrate 10 in the same or similar method as in the previous embodiment, to form hybrid structure 50. Then, nano structure 60 is grown on CNTs 40 to obtain a hybrid structure 50 illustrated in FIG. 9.

As described above, when catalyst layer 30 includes Zn, the Zn may remain in an apical end of the grown CNTs 40.

Meanwhile, before nano structure 60 is grown, catalyst layer 30 may be selectively removed so that only Zn remains in the apical end of the CNTs 40. Such selective removing of a material being formed from catalyst layer 30 may be performed by, for example, a post treatment process by using a laser or plasma. Referring to FIG. 8, a Zn layer 41 is present in the apical end of CNTs 40 after selective removing of the material of the catalyst layer 30.

As described above, when Zn is present in the apical end of CNTs 40, nano structure 60 may be a ZnO nano structure obtained using Zn as a seed, that is, ZnO nano robs. As a result, the hybrid structure 50 that consists of CNTs 40 and ZnO nano robs grown on CNTs 40 may be obtained through this process.

The nano structure 60 can be formed by hydrothermal growth. The substrate 10 on which the CNTs 40 having an apical end containing Zn is grown, is dipped into a hexamethylenamine aqueous solution. Then, the resultant hexamethylenamine aqueous solution in which the substrate 10 has been dipped, is heated in a water bath while a zinc nitrate aqueous solution is added to the both. As a result, ZnO nano robs can be grown on the CNTs 40 by using the Zn present in the apical ends of the CNTs 40 as a seed.

Meanwhile, in nano structure 60, for example, a ZnO nano rob may be formed to have N-type semiconductor properties, which is well known. Therefore, in hybrid structure 50, CNTs 40 may be formed to have p-type semiconductor properties. Since CNTs 40 can be formed to have semiconducting properties or electrically conductive properties, CNTs 40 of hybrid structure 50 can be formed to have P-type semiconductor properties.

As described above, when CNTs 40 are formed to have p-type semiconducting properties and the nano structure 60 is formed to have N-type semiconducting properties, and a p-n junction 70 may be formed between the CNTs 40 and the nano structure 60, for example, ZnO nano robs.

When a current is applied to the hybrid structure 50, electrons may be combined with holes in the p-n junction 70 to generate light. Therefore, when the hybrid structure 50 is used in a device, the device can generate colored light by itself.

FIG. 10 is a schematic view of a light emitting device including the hybrid structure of FIG. 9, fabricated as an embodiment of the present invention.

Referring to FIG. 10, the light emitting device may be constructed with a substrate 10; a hybrid structure 50 including CNTs 40 and a nano structure, formed together on substrate 10; and first and second electrodes 80 and 90 electrically connected to hybrid structure 50.

As described above, in the hybrid structure 50, the nano structure 60 may include ZnO. For example, the nano structure 60 may be ZnO nano robs.

A p-n junction 70 may be formed between CNTs 40 and the nano structure 60. When a current is applied through the first and second electrodes 80 and 90, electrons may be combined with holes in the p-n junction 70 to generate an emission of light.

Referring to FIG. 10, first electrode 80 is formed between substrate 10 and a buffer layer 20, and second electrode 90 is formed on hybrid structure 50. The location of first electrode 80 is not limited however to the structure illustrated in FIG. 10. In some cases, buffer layer 20 can act as an electrode layer, and first electrode 80 may not be formed.

Second electrode 90 may be an optically transparent electrode. When substrate 10 is a transparent substrate, first electrode 80 may be a transparent electrode.

The light emitting device including the hybrid structure 50 can generate light omitted from p-n junction 70 between CNTs 40 and the nano structure 60. Therefore, the light emitting device can generate colored light by itself.

The light emitting device fabricated according to the principles of the present invention can be used as a back light (BLU) for a liquid crystal display (LCD). Specifically, the light emitting device can generate light by itself, and thus a low-voltage fluorescent material is not required when the light emitting device is used as a BLU for LCD.

The light emitting device so fabricated may be used in a wide range of applications including a BLU for LCD.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of growing carbon nanotubes (CNTs), the method comprised of:
facilitating growth of CNTs in a multi-layer structure by forming a catalyst layer; and
injecting a carbon-containing gas into the catalyst layer to grow CNTs.

2. The method of claim 1, wherein the catalyst layer comprises: at least one first layer which comprises Zn; and at least one second layer which does not comprise Zn, in which the first layer and the second layer are alternately stacked.

3. The method of claim 2, wherein the second layer comprises Ni.

4. The method of claim 1, the method comprised of forming catalytic grains in the catalyst layer by surface-treating the catalyst layer.

5. The method of claim 4, wherein the catalytic grains are formed by a plasma treatment, a laser treatment, or a heat treatment.

6. The method of claim 1, wherein the carbon-containing gas comprises at least one gas selected from the group consisting of CH₄, C₂H₂, C₂H₄, C₂H₆, CO, and CO₂ that is injected together with at least one gas selected from the group consisting of H₂, N₂, O₂, H₂O, and Ar.

7. The method of claim 1, further forming a buffer layer between the substrate and the catalyst layer.

8. The method of claim 1, wherein the catalyst layer comprises at least one first layer comprising Zn and at least one second layer comprising Ni, wherein the first and second layers are alternately stacked,
forming catalytic grains in the catalyst layer by surface treating the catalyst layer, and
forming a buffer layer between the substrate and the catalyst layer.

9. The method of claim 1, wherein the catalyst layer comprises Zn, further comprising selectively removing a material of the catalyst layer such that Zn remains in an end portion of the grown CNTs.

10. A method of forming a hybrid structure, the method comprising:
forming CNTs using the method of claim 1; and
forming a hybrid structure by growing a nano structure on the CNTs.

11. The method of claim 10, wherein the catalyst layer comprises: at least one first layer which comprises Zn; and at least one second layer which does not comprise Zn, in which the first layer and the second layer are alternately stacked.

12. The method of claim 11, wherein the second layer comprises Ni.

13. The method of claim 10, comprised of forming catalytic grains by surface-treating the catalyst layer.

14. The method of claim 13, wherein the catalytic grains are formed by a plasma treatment, a laser treatment, or a heat treatment.

15. The method of claim 10, wherein the carbon-containing gas comprises at least one gas selected from the group consisting of CH₄, C₂H₂, C₂H₄, C₂H₆, CO, and CO₂ that is injected together with at least one gas selected from the group consisting of H₂, N₂, O₂, H₂O, and Ar.

16. The method of claim 10, further forming a buffer layer between the substrate and the catalyst layer.

17. The method of claim 10, wherein the catalyst layer comprises: at least one first layer which includes Zn; and at least one second layer which includes Ni, in which the first layer and the second layer are alternately stacked,
forming catalytic grains in the catalyst layer by surface-treating the catalyst layer, and
forming a buffer layer between the substrate and the catalyst layer.

18. The method of claim 10, comprised of growing the catalyst layer with remanents of the catalyst layer in end portions of the grown CNTs comprising Zn, and
the nano structure comprising ZnO.

19. The method of claim 18, comprised of growing the nano structure using the Zn remaining in end portions of the grown CNTs as a seed.

20. The method of claim 10, comprised of forming a p-n junction between the CNTs and the nano structure.

21. The method of claim 10, wherein the catalyst layer comprises Zn, before growing of the nano structure, and the method further comprised of selectively removing a material of the catalyst layer such that Zn remains in an end portion of the grown CNTs.

22. A CNT having a multilayer that is used as a catalyst in an apical end and being formed on a substrate.

23. The CNT of claim 22, wherein the multilayer comprises at least one first layer that comprises Zn and at least one second layer that does not comprise Zn, wherein the first layer and the second layer are alternately stacked.

24. The CNT of claim 23, wherein the second layer comprises Ni.

25. The CNT of claim 23, wherein the multiple layer has been selectively removed such that Zn remains in an apical end of the CNT.

26. A hybrid structure comprising:
a CNT grown on a substrate by using a catalyst having a multi-layer structure; and
a nano structure grown on the CNT.

27. The hybrid structure of claim 26, comprised of forming a p-n junction between the CNT and the nano structure.

28. The hybrid structure of claim 26, wherein the nano structure comprises ZnO.

29. The hybrid structure of claim 28, comprised of apical ends of the CNTs comprise Zn that is used in the multi-layer catalyst structure, and the nano structure is formed using the Zn as a seed.

30. A light emitting device comprising:
a substrate;
the hybrid structure of claim 26 disposed on the substrate; and
an electrode electrically connected to the hybrid structure.

31. The light emitting device of claim 30, comprised of a p-n junction formed between the CNT and a nano structure formed in the hybrid structure.

32. The light emitting device of claim 30, wherein the nano structure comprises ZnO.

33. The light emitting device of claim 32, comprised of apical ends of the CNTs comprise Zn that is used in multi-layer catalyst structure, and the nano structure is formed using the Zn as a seed.

34. A liquid crystal display device comprised of the emitting device of claim 30, disposed as a back light for the liquid crystal display.
